(19) United States
(12) Patent Application Publication
(10) Pub. No.: US 2026/0293608 A1
(43) Pub. Date: Sep. 24, 2026

(54) WAFER TRANSFER DEVICE

(71) Applicant: NANYA TECHNOLOGY CORPORATION, New Taipei City (TW)

(72) Inventors: Hong Ru WU, New Taipei City (TW); Sun-Fu CHOU, New Taipei City (TW)

(21) Appl. No.: 19/086,147

(22) Filed: Mar. 21, 2025

(51) Int. Cl. H01L 21/687

(52) U.S. Cl. CPC H10P 72/7611; H10P 72/7624

(57) ABSTRACT

A wafer transfer device comprises a first wall, a second wall, a third wall, a first supporting base, and a second supporting base. The second wall is substantially parallel to the first wall and spaces apart from each other in a first direction. The third wall is connected between the first wall and the second wall. The first supporting base is connected to a bottom of the first wall and extending toward the second wall. The first supporting base has a first contact surface. The second supporting base is connected to a bottom of the second wall and extending toward the first wall. The second supporting base has a second contact surface substantially coplanar with the first contact surface. Each of the first contact surface and the second contact surface has a width equal to or less than 6 mm in the first direction.

### BACKGROUND

### Field of Invention

The present disclosure relates to a wafer transfer device. More particularly, the present disclosure relates to a high stability manual wafer transfer device for safety transferred a wafer with no contamination and damage.

### Description of Related Art

During the wafer manufacturing process, if an abnormal wafer needs to be manually removed, it is typically done using a “vacuum picker pen” or “wafer clip” to extract the defective wafer and place it into a wafer transport box for subsequent evaluation and processing. However, the “vacuum picker pen” or “wafer clip” is prone to accidental contact with the wafer due to hand movement or instability, leading to wafer contamination or even damage.

Therefore, a wafer transfer device capable of addressing the aforementioned issues is needed.

### SUMMARY

An aspect of the present disclosure relates a wafer transfer device, comprising a first wall, a second wall, a third wall, a first supporting base, and a second supporting base. The second wall is substantially parallel to the first wall and spaces apart from each other in a first direction. The third wall is connected between the first wall and the second wall. The first supporting base is connected to a bottom of the first wall and extending toward the second wall. The first supporting base has a first contact surface. The second supporting base is connected to a bottom of the second wall and extending toward the first wall. The second supporting base has a second contact surface substantially coplanar with the first contact surface. Each of the first contact surface and the second contact surface has a width equal to or less than about 6 mm in the first direction.

In some embodiments of the present disclosure, the wafer transfer device further comprises a third supporting base. The third supporting base is connected to a bottom of the third wall and extending away from the third wall. The third supporting base has a third contact surface substantially coplanar with the first contact surface. The third contact surface has a width equal to or less than about 6 mm in a second direction perpendicular to the first direction.

In some embodiments of the present disclosure, a length of the first wall and a length of the second wall in a second direction are greater than a length of the third wall in the first direction. The second direction is perpendicular to the first direction.

In some embodiments of the present disclosure, the first wall, the second wall, and the third wall form a U shape.

In some embodiments of the present disclosure, the wafer transfer device further comprises a stability structure. The stability structure is connected to a top of the first wall and a top of the second wall. Wherein the tops of the first wall and the second wall are opposite to the bottoms of the first wall and the second.

In some embodiments of the present disclosure, the stability structure and the third wall are respectively located on opposite ends of the first wall and the second wall.

In some embodiments of the present disclosure, the first wall, the second wall, the third wall, and the stability structure form a rectangle.

In some embodiments of the present disclosure, the wafer transfer device further comprises a handle connected to the third wall.

Another aspect of the present disclosure relates a wafer transfer device, comprising a first wall, a second wall, a third wall, a first supporting base, and a second supporting base. The second wall is substantially parallel to the first wall and spaced apart from each other in a first direction. The third wall is connected between the first wall and the second wall. The first supporting base is connected to a bottom of the first wall and extending toward the second wall. The first supporting base has a first bottom surface and a first inclined surface inclined at an angle relative to the first bottom surface. The second supporting base is connected to a bottom of the second wall and extending toward the first wall. The second supporting base has a second bottom surface and a second inclined surface inclined at an angle relative to the second bottom surface.

In some embodiments of the present disclosure, the angle between the first inclined surface and the first bottom surface is less than about 10 degrees, as is the angle between the second inclined surface and the second bottom surface.

In some embodiments of the present disclosure, the second bottom surface is substantially coplanar with the first bottom surface.

In some embodiments of the present disclosure, the wafer transfer device further comprises a third supporting base. The third supporting base is connected to a bottom of the third wall and extending away from the third wall. The third supporting base has and a third bottom surface and a third inclined surface inclined at an angle relative to the third bottom surface.

In some embodiments of the present disclosure, the angle between the third inclined surface and the third bottom surface is less than about 10 degrees.

In some embodiments of the present disclosure, the third bottom surface is substantially coplanar with the first bottom surface and the second bottom surface.

In some embodiments of the present disclosure, the wafer transfer device further comprises a stability structure. The stability structure is connected to a top of the first wall and a top of the second wall. The tops of the first wall and the second wall are opposite to the bottoms of the first wall and the second wall.

In some embodiments of the present disclosure, the stability structure and the third wall are respectively located on opposite ends of the first wall and the second wall.

In some embodiments of the present disclosure, the wafer transfer device further comprises a handle connected to the third wall.

In summary, the wafer transfer device disclosed herein ensures that during manual handling of wafers, the risk of contamination or damage caused by human error is minimized. Furthermore, as the disclosed wafer transfer device contacts the wafer's inactive annular region through a contact surface and lifts the wafer upward, it significantly reduces the risk of operators touching the wafer with their hands.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a perspective view of a wafer transfer device according to some embodiments of the present disclosure;

FIG. 2 is a side view of the wafer transfer device according to some embodiments of the present disclosure;

FIG. 3 is a perspective view of the wafer transfer device with a wafer according to some embodiments of the present disclosure;

FIG. 4 is a perspective view of a wafer transfer device according to some embodiments of the present disclosure;

FIG. 5 is a side view of the wafer transfer device with the wafer according to some embodiments of the present disclosure; and

FIG. 6 is a step-by-step flow chart of processing an abnormal wafer according to some embodiments of the present disclosure.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts.

It should be understood that when an element or layer is referred to as being “connected to” or “coupled to” another element or layer, it can be directly connected to or coupled to another element or layer, or intervening elements or layers may be present.

To clearly illustrate the positional relationships and alignments between the various components, coordinate axes are indicated in the diagrams, namely the first axis A1, the second axis A2, and the third axis A3.

During the wafer manufacturing process, if the equipment's automatic reset system cannot function and the robotic arm is unable to operate, and an abnormal wafer is detected, manual removal of the abnormal wafer is required. Typically, when manually removing an abnormal wafer, the operator uses a wafer transfer device to extract the abnormal wafer from the production line and place it into an empty wafer transport box for subsequent processing.

To reduce or even eliminate the risk of operators accidentally touching the wafer during manual handling, the present disclosure provides a wafer transfer device. The wafer transfer device is capable of vertically lifting an abnormal wafer from beneath its position on the production line where the abnormality occurred and safely placing it into a wafer transport box or, after inspection, returning it to its original position.

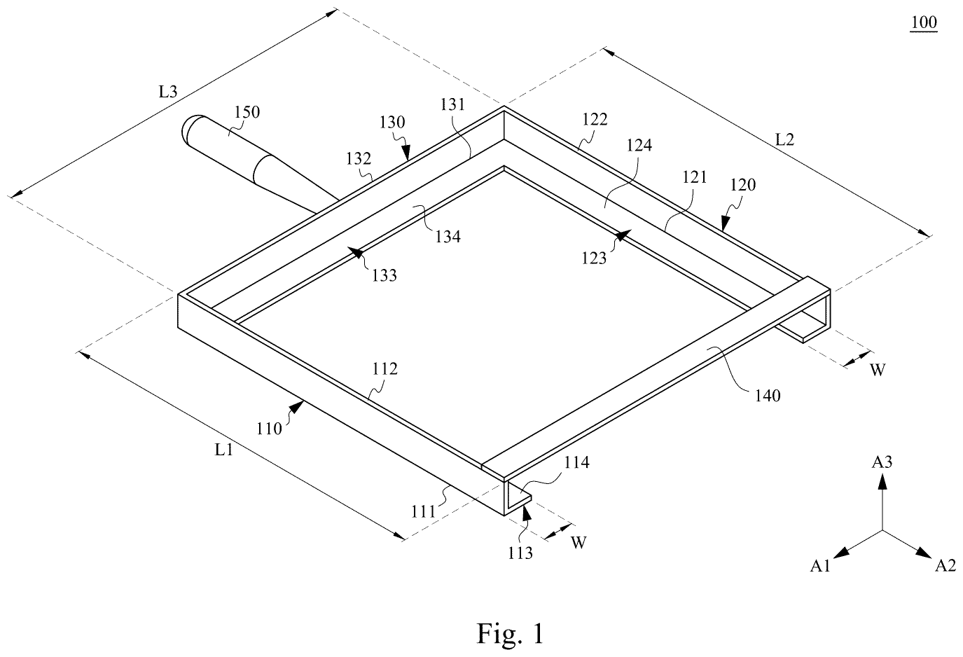

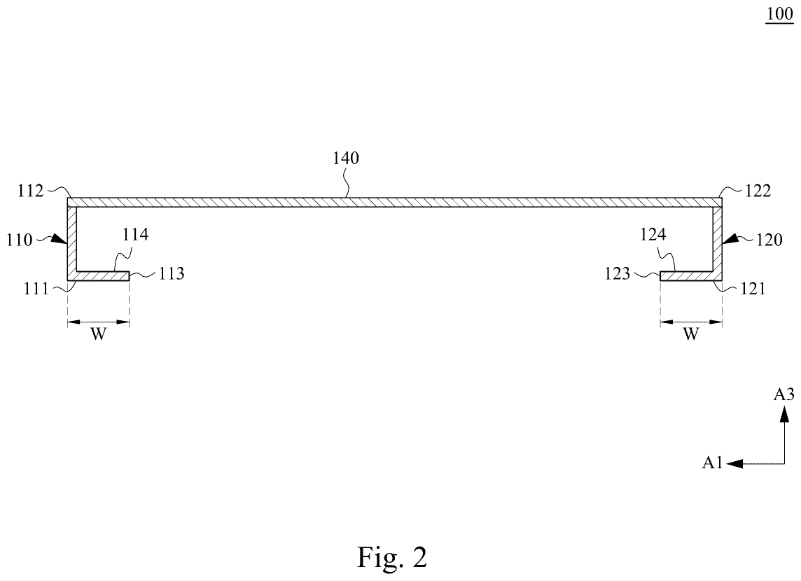

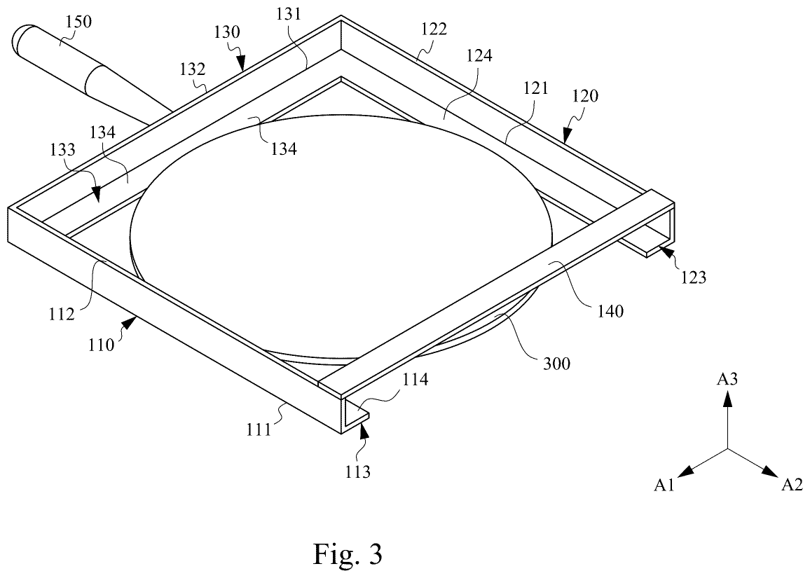

Reference is made to FIG. 1, FIG. 2, and FIG. 3. FIG. 1 is a perspective view of a wafer transfer device 100 according to some embodiments of the present disclosure. FIG. 2 is a side view schematic of the wafer transfer device 100 according to some embodiments of the present disclosure. FIG. 3 is a perspective view of the wafer transfer device 100 with a wafer 300 according to some embodiments of the present disclosure. In some embodiments of the present disclosure, as shown in FIG. 3, the wafer 300 is a 12 inch wafer, but the present disclosure is not limited to thereto. In some embodiments of the present disclosure, the size of the wafer transfer device 100 can be adjusted according to the size of the wafer 300.

In some embodiments of the present disclosure, as shown in FIG. 1 and FIG. 2, the wafer transfer device 100 includes a first wall 110, a second wall 120, a third wall 130, a first supporting base 113, and a second supporting base 123. The second wall 120 is substantially parallel to the first wall 110 and spaces apart from each other in a first direction. The third wall 130 is connected between the first wall 110 and the second wall 120. The first supporting base 113 is connected to a bottom 111 of the first wall 110 and extending toward the second wall 120. The second supporting base 123 is connected to a bottom 121 of the second wall 120 and extending toward the first wall 110. The first direction is along the first axis A1.

In some embodiments of the present disclosure, the first supporting base 113 has a first contact surface 114. In some embodiments of the present disclosure, the second supporting base 123 has a second contact surface 124 substantially coplanar with the first contact surface 114. In some embodiments of the present disclosure, each of the first contact surface 114 and the second contact surface 124 has a width equal to or less than about 6 mm in the first direction. In some embodiments of the present disclosure, each of the first contact surface 114 and the second contact surface 124 has a width equal to or less than about 3 mm in the first direction. For example, the width of the first contact surface 114 and the second contact surface 124 may be about 3 mm, about 4 mm, about 5 mm, or about 6 mm.

Specifically, the contact surface of the wafer transfer device 100 is designed to touch the outermost invalid annular region of the wafer 300. Generally, starting from the outermost edge of the wafer 300 toward its center, the invalid annular region of the wafer 300 is typically within a range of about 3 mm. Therefore, considering the dimensions of the wafer transfer device 100 and the wafer 300, it is preferable for the contact surfaces 114 and 124 of the wafer transfer device 100 to be less than about 6 mm.

In some embodiments of the present disclosure, as shown in FIG. 1, the wafer transfer device 100 further includes a third supporting base 133. The third supporting base 133 is connected to a bottom 131 of the third wall 130 and extending away from the third wall 130. In some embodiments of the present disclosure, the third supporting base 133 has a third contact surface 134 substantially coplanar with the first contact surface 114. In some embodiments of the present disclosure, the third contact surface 134 has a width equal to or less than about 6 mm in a second direction perpendicular to the first direction. In some embodiments of the present disclosure, the third contact surface 134 has a width equal to or less than about 3 mm in the first direction. For example, the width of the third contact surface 134 may be about 3 mm, about 4 mm, about 5 mm, or about 6 mm. The second direction is along the second axis A2.

In some embodiments of the present disclosure, as shown in FIG. 1, a length L1 of the first wall 110 and a length L2 of the second wall 120 in the second direction are greater than a length L3 of the third wall 130 in the first direction. Since the lengths L1, L2 of the first wall 110 and the second wall 120 are greater than that the length L3 of the third wall 130, the wafer is less likely to fall out from the notch away from the third wall 130 when being carried. This enhances the stability of the wafer transfer device 100. In some embodiments of the present disclosure, the first wall 110, the second wall 120, and the third wall 130 form a U shape.

In some embodiments of the present disclosure, as shown in FIG. 1 and FIG. 2, the wafer transfer device 100 further includes a stability structure 140. The stability structure 140 is connected to a top 112 of the first wall 110 and a top 122 of the second wall 120. The tops 112, 122 of the first wall 110 and the second wall 120 are opposite to the bottoms 111, 121 of the first wall 110 and the second 120. In some embodiments of the present disclosure, the stability structure 140 and the third wall 130 are respectively located on opposite ends of the first wall 110 and the second wall 120. The stability structure 140 is used to enhance the structural strength of the wafer transfer device 100, preventing the first wall 110 and the second wall 120 from wobbling at their ends away from the third wall 130 due to insufficient structural strength. In some embodiments of the present disclosure, the first wall 110, the second wall 120, the third wall 130, and the stability structure 140 form a rectangle.

In some embodiments of the present disclosure, as shown in FIG. 1, the wafer transfer device 100 further includes a handle 150 connected to the third wall 130. The handle 150 is configured to allow an operator to use the wafer transfer device 100 in a comfortable manner.

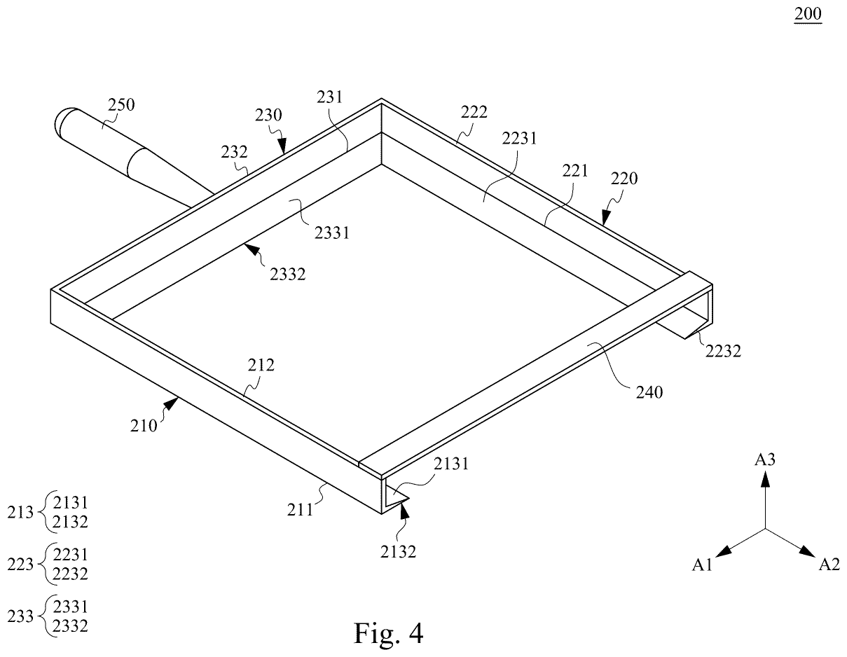

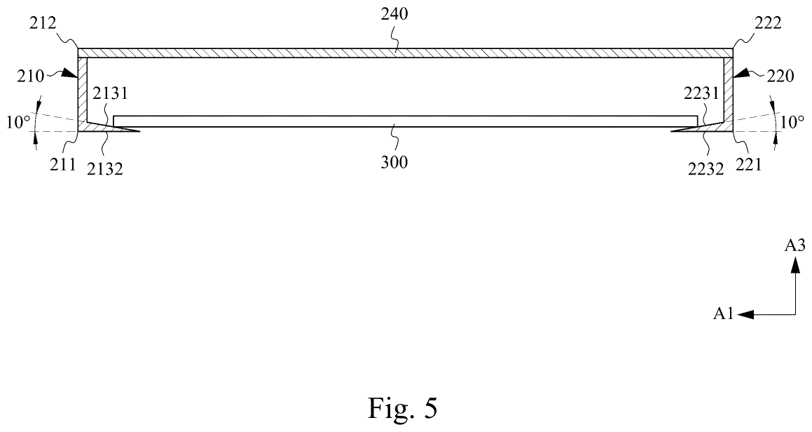

Reference is made to FIG. 4 and FIG. 5. FIG. 4 is a perspective view of a wafer transfer device 200 according to some embodiments of the present disclosure. FIG. 5 is a side view schematic of the wafer transfer device 200 with a wafer 300 according to some embodiments of the present disclosure.

In some embodiments of the present disclosure, as shown in FIG. 4, the wafer transfer device 200 includes a first wall 210, a second wall 220, a third wall 230, a first supporting base 213, and a second supporting base 223. The configurations and configurations of the first wall 210, the second wall 220, the third wall 230, the first supporting base 213, and the second supporting base 223 are similar to those of the wafer transfer device 100 and will not be repeated here.

In some embodiments of the present disclosure, as shown in FIG. 4, the first supporting base 213 is connected to a bottom 211 of the first wall 210 and extending toward the second wall 220. In some embodiments of the present disclosure, the first supporting base 213 has and a first bottom surface 2132 and a first inclined surface 2131 inclined at an angle relative to the first bottom surface 2132. In some embodiments of the present disclosure, as shown in FIG. 4, second supporting base 223 is connected to a bottom 221 of the second wall 220 and extending toward the first wall 210. In some embodiments of the present disclosure, the second supporting base 223 has and a second bottom surface 2232 and a second inclined surface 2231 inclined at an angle relative to the second bottom surface 2232. In some embodiments of the present disclosure, the second bottom surface 2232 is substantially coplanar with the first bottom surface 2132.

In some embodiments of the present disclosure, as shown in FIG. 5, the angle between the first inclined surface 2131 and the first bottom surface 2132 is less than about 10 degrees, as is the angle between the second inclined surface 2231 and the second bottom surface 2232. For example, the angle may be about 10 degrees, about 9 degrees, about 8 degrees, about 7 degrees, about 6 degrees, about 5 degrees, about 4 degrees, about 3 degrees, about 2 degrees, or about 1 degree. Specifically, the wafer transfer device 200 can pick up wafers 300 more easily by tilting the inclined surfaces 2131 and 2231 of the supporting bases 213 and 223 at an angle to the bottom surfaces 2132 and 2232 of the supporting bases 213 and 223, respectively.

In some embodiments of the present disclosure, as shown in FIG. 4, the wafer transfer device 200 further comprises a third supporting base 233. The third supporting base 233 is connected to a bottom 231 of the third wall 230 and extending away from the third wall 230. The third supporting base 233 has and a third bottom surface 2332 and a third inclined surface 2331 inclined at an angle relative to the third bottom surface 2332. In some embodiments of the present disclosure, the third bottom surface 2332 is substantially coplanar with the first bottom surface 2132 and the second bottom surface 2232.

In some embodiments of the present disclosure, the angle between the third inclined surface 2331 and the third bottom surface 2332 is less than about 10 degrees. For example, the angle may be about 10 degrees, about 9 degrees, about 8 degrees, about 7 degrees, about 6 degrees, about 5 degrees, about 4 degrees, about 3 degrees, about 2 degrees, or about 1 degree. Specifically, the wafer transfer device 200 can pick up wafers 300 more easily by tilting the inclined surface 2331 of the supporting base 233 at an angle to the bottom surface 2332 of the supporting base 233.

In some embodiments of the present disclosure, the wafer transfer device 200 further comprises a stability structure 240. The stability structure 240 is connected to a top 212 of the first wall 210 and a top 222 of the second wall 220. The tops 212, 222 of the first wall 210 and the second wall 220 are opposite to the bottoms 211, 221 of the first wall 210 and the second wall 220. In some embodiments of the present disclosure, the stability structure 240 and the third wall 230 are respectively located on opposite ends of the first wall 210 and the second wall 220.

In some embodiments of the present disclosure, the wafer transfer device 200 further comprises a handle 250 connected to the third wall 230. The handle 250 is configured to allow an operator to use the wafer transfer device 200 in a comfortable manner.

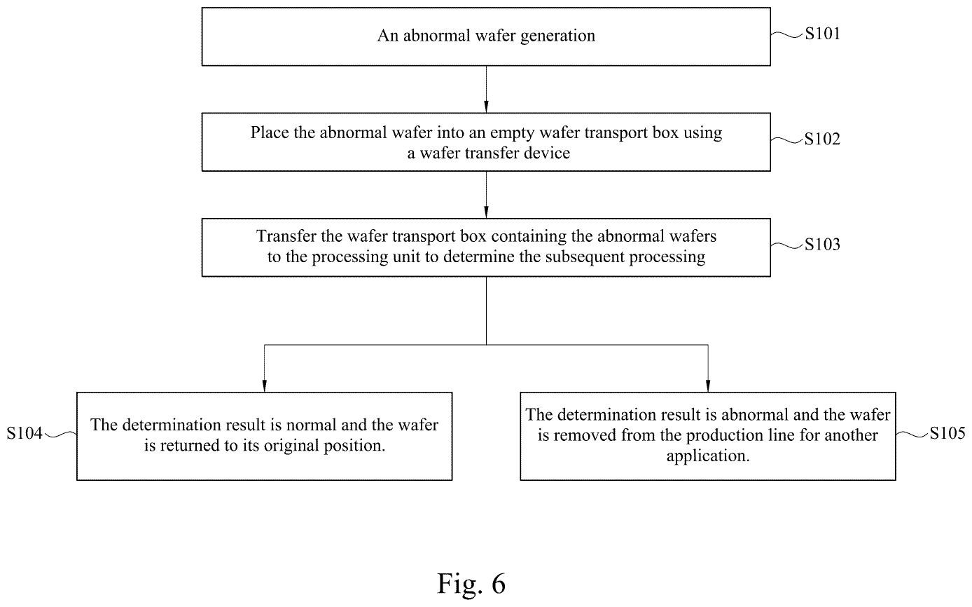

Reference is made to FIG. 6. FIG. 6 is a step-by-step flow chart of processing an abnormal wafer according to some embodiments of the present disclosure. The processing flow of abnormal wafers disclosed herein shows that the original abnormal wafer processing flow has been improved by using the wafer transfer device of the present disclosure.

The processing begins at step S101, where an abnormal wafer is generated and detected in the wafer manufacturing process. If the automatic reset system of the equipment fails to function and the robotic arm is unable to operate, the abnormal wafer must to be removed manually.

The processing continues with step S102. The operator uses a wafer transfer device to remove the abnormal wafer from the production line and place it into an empty wafer transport box for further processing.

The processing continues with step S103. The wafer transport box carrying the abnormal wafer will is transferred to the processing unit to determine the subsequent processing.

The processing continues with step S104 or step S105 based on the determine result. If the determine results indicate that the wafer is normal, it is returned to its original position using the wafer transfer device of the present disclosure. If the determine results confirm a problem with the wafer, it is transferred to another unit for further processing and reused for non-production applications.

While the processing is illustrated and described above as a series of steps or events, it will be appreciated that the illustrated ordering of such steps or events are not to be interpreted in a limiting sense. For example, some steps may occur in different orders and/or concurrently with other steps or events apart from those illustrated and/or described herein. In addition, not all illustrated steps may be required to implement one or more aspects or embodiments of the description herein. Further, one or more of the steps depicted herein may be carried out in one or more separate steps and/or phases.

In other words, when an abnormal wafer is detected on the production line, the operator uses the wafer transfer device of the present disclosure to transfer the abnormal wafer to a wafer transport box, which is then sent to the relevant unit for inspection. If the inspection results indicate that the wafer is normal, it is returned to its original position using the wafer transfer device of the present disclosure. If the inspection results confirm a problem with the wafer, it is transferred to another unit for further processing and reused for non-production applications.

By using the wafer transfer device of the present disclosure, the risk of operators accidentally touching the wafer can be avoided. As a result, the handling process for abnormal wafers no longer needs to account for the risk of scrap caused by human error. This further reduces personnel risk, decreases the wafer damage rate, shortens the abnormal handling time, and improves work efficiency.

In summary, the wafer transfer device disclosed herein ensures that during manual handling of wafers, the risk of contamination or damage caused by human error is minimized. Furthermore, as the disclosed wafer transfer device contacts the wafer's inactive annular region through a contact surface and lifts the wafer upward, it significantly reduces the risk of operators touching the wafer with their hands.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this present disclosure provided they fall within the scope of the following claims.

What is claimed is:

1. A wafer transfer device, comprising:
a first wall;
a second wall substantially parallel to the first wall and spaced apart from each other in a first direction;
a third wall connected between the first wall and the second wall;
a first supporting base connected to a bottom of the first wall and extending toward the second wall, the first supporting base having a first contact surface; and
a second supporting base connected to a bottom of the second wall and extending toward the first wall, the second supporting base having a second contact surface substantially coplanar with the first contact surface;
wherein each of the first contact surface and the second contact surface has a width equal to or less than about 6 mm in the first direction.

2. The wafer transfer device of claim 1, further comprising a third supporting base connected to a bottom of the third wall and extending away from the third wall, wherein the third supporting base has a third contact surface substantially coplanar with the first contact surface, and the third contact surface has a width equal to or less than about 6 mm in a second direction perpendicular to the first direction.

3. The wafer transfer device of claim 1, wherein a length of the first wall and a length of the second wall in a second direction perpendicular to the first direction are greater than a length of the third wall in the first direction.

4. The wafer transfer device of claim 1, wherein the first wall, the second wall, and the third wall form a U shape.

5. The wafer transfer device of claim 1, further comprising a stability structure connected to a top of the first wall and a top of the second wall, wherein the tops of the first wall and the second wall are opposite to the bottoms of the first wall and the second.

6. The wafer transfer device of claim 5, wherein the stability structure and the third wall are respectively located on opposite ends of the first wall and the second wall.

7. The wafer transfer device of claim 6, wherein the first wall, the second wall, the third wall, and the stability structure form a rectangle.

8. The wafer transfer device of claim 1, further comprising a handle connected to the third wall.

9. A wafer transfer device, comprising:
a first wall;
a second wall substantially parallel to the first wall and spaced apart from each other in a first direction;
a third wall connected between the first wall and the second wall;
a first supporting base connected to a bottom of the first wall and extending toward the second wall, the first supporting base having a first bottom surface and a first inclined surface inclined at an angle relative to the first bottom surface; and
a second supporting base connected to a bottom of the second wall and extending toward the first wall, the second supporting base having a second bottom surface and a second inclined surface inclined at an angle relative to the second bottom surface.

10. The wafer transfer device of claim 9, wherein the angles are less than about 10 degrees.

11. The wafer transfer device of claim 9, wherein the second bottom surface is substantially coplanar with the first bottom surface.

12. The wafer transfer device of claim 9, further comprising a third supporting base connected to a bottom of the third wall and extending away from the third wall, the third supporting base having and a third bottom surface and a third inclined surface inclined at an angle relative to the third bottom surface.

13. The wafer transfer device of claim 12, wherein the angle of the third supporting base is less than about 10 degrees.

14. The wafer transfer device of claim 12, wherein the third bottom surface is substantially coplanar with the first bottom surface and the second bottom surface.

15. The wafer transfer device of claim 9, further comprising a stability structure connected to a top of the first wall and a top of the second wall, wherein the tops of the first wall and the second wall are opposite to the bottoms of the first wall and the second wall.

16. The wafer transfer device of claim 15, wherein the stability structure and the third wall are respectively located on opposite ends of the first wall and the second wall.

17. The wafer transfer device of claim 9, further comprising a handle connected to the third wall.
